(19) United States
(12) Patent Application Publication
(10) Pub. No.: US 2011/0153058 A1
(43) Pub. Date: Jun. 23, 2011

(54) MULTIMEDIA STORAGE DEVICE

(76) Inventor: James Howard Johnson, Spotsylvania, VA (US)

(21) Appl. No.: 12/889,837

(22) Filed: Sep. 24, 2010

Related U.S. Application Data
(60) Provisional application No. 61/335,523, filed on Dec. 23, 2009.

(51) Int. Cl. G06F 7/00; H05K 5/00; H05K 5/02; A47B 96/00; G06F 3/048

(52) U.S. Cl. 700/214; 312/223.1; 312/9.9; 312/327; 715/764

(57) ABSTRACT

A method, system and apparatus for housing data storage devices. The method, system and apparatus can include an enclosure for receiving, sorting, storing and retrieving data storage devices. Additionally, the method, system and apparatus can include an interface and display that allow for the manipulation of data storage devices.

### RELATED APPLICATIONS

This application claims priority under 37 C.F.R. §120 to U.S. Provisional Patent Application 61/335,523, filed on Dec. 23, 2009 and entitled SAFESTORE VAULT, the entire content of which is hereby incorporated by reference.

### BACKGROUND

Portable media devices, data storage devices and discs are expanding in both number and format. Compact Discs, Digital Video Disks, portable flash memory drives, memory cards, and a host of other media to store data are available. New formats are frequently being introduced that vary in capacity, cost, physical size, and software standard. The data that these media contain can be important for either productivity or leisure.

While higher storage media formats are available, consumers often buy media devices and discs with data preloaded and with copy protection, making consumers unable to transfer the media to a single storage device with larger capacity. In addition, although portable flash memory drives may have a comparatively limited storage capacity, the drives are inexpensive and physically small, allowing for easy or convenient transport of data. Consequently, many people opt to use a multitude of portable flash memory drives with different data stored on different drives instead of opting to store all data on a single device. Various recording devices, such as digital cameras or camcorders, often utilize a variety of media formats, requiring users to own different memory cards for different devices.

However, the storage, organization, and transport of a large number of media devices or discs can be cumbersome. When attempting to transport a media device or disc with particular data, it may be difficult to locate and correctly identify the particular media device or disc containing the particular data. Even when labeling discs and storing them in a case or container, one still needs to browse through the case or container to locate the desired disc. Portable media devices can provide an even greater challenge, as their small physical size makes them difficult to label and their appearance is often similar. In addition, many of these devices are relatively fragile and must be handled carefully in order to ensure the safety of stored data.

### SUMMARY

In one exemplary embodiment, a storage apparatus may be described. The storage apparatus can have an enclosure with an aperture; an automated data storage device receiving, storing and sorting mechanism; storage capacity for a plurality of data storage devices; and a user interface.

In another exemplary embodiment, a method for storing and organizing data storage devices can be described. The method can include placing a data storage device into storage receptacle; moving the storage receptacle to an inside portion of an enclosure; sorting the storage receptacle according the data storage device in the storage receptacle; performing management tasks; retrieving the storage receptacle from the enclosure; and ejecting the data storage device.

Another exemplary embodiment can describe a system for storing digital media. The system can have means for programming data; means for mechanically accepting various formats of digital media; means for mechanically storing the various formats of digital media; means for mechanically sorting the various formats of digital media; means for reading the various formats of digital media; means for naming the various formats of digital media; and means for retrieving the various formats of digital media.

### BRIEF DESCRIPTION OF THE FIGURES

Advantages of embodiments of the present invention will be apparent from the following detailed description of the exemplary embodiments. The following detailed description should be considered in conjunction with the accompanying figures in which:

FIG. 1A is a front view of an exemplary embodiment of a storage system.

FIG. 1B is another front view of an exemplary embodiment of a storage system

FIG. 2 is a rear view of an exemplary embodiment of a storage system.

FIG. 3 is a rear oblique view of an exemplary embodiment of a storage system.

FIG. 4 is a front oblique view of an exemplary internal storage structure.

FIG. 5 is a side view of an exemplary control arm.

FIG. 6A is a front view of an exemplary storage receptacle.

FIG. 6B is a cutaway view of an exemplary storage receptacle.

FIG. 6C is a front view of another exemplary storage receptacle.

FIG. 6D is a cutaway view of another exemplary storage receptacle.

FIG. 6E is a front view of another exemplary storage receptacle.

FIG. 6F is a cutaway view of another exemplary storage receptacle.

### DETAILED DESCRIPTION

Aspects of the invention are disclosed in the following description and related drawings directed to specific embodiments of the invention. Alternate embodiments may be devised without departing from the spirit or the scope of the invention. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the invention”, “embodiments” or “invention” do not require that all embodiments of the invention include the discussed feature, advantage or mode of operation. “Data” should be understood to be any information in either organized or unorganized form and in any format.

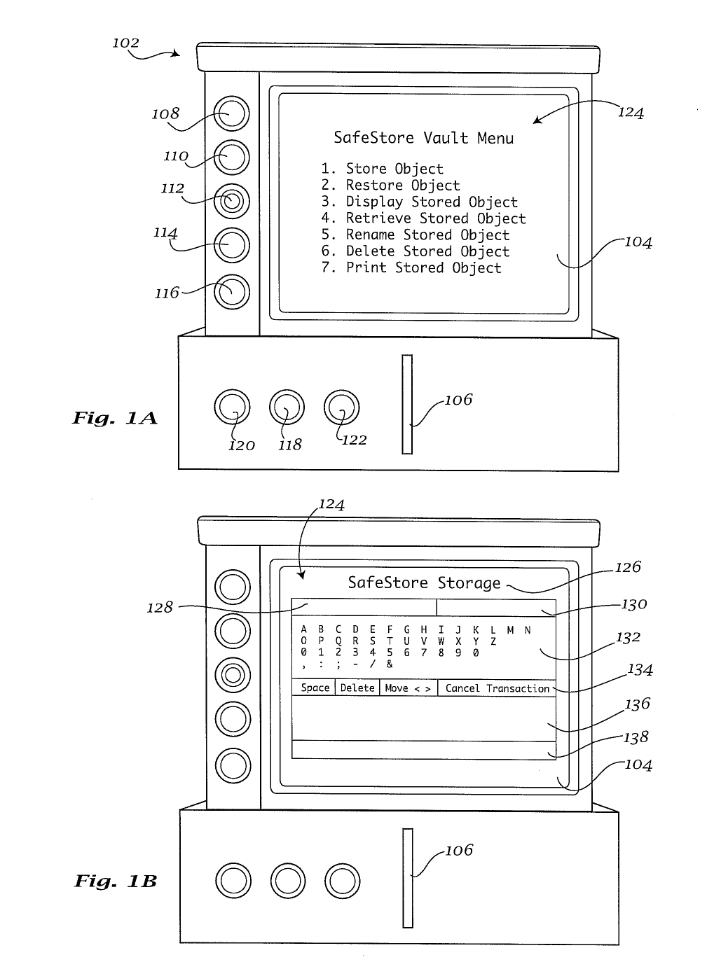

Generally referring to exemplary FIGS. 1-6, embodiments described herein may include a system for managing the storage and retrieval of various data storage devices or products, including, but not limited to, Digital Video Discs (DVDs), Compact Discs (CDs), memory cards, memory sticks, and any other physical data storage devices. Exemplary embodiments of methods, systems and apparatuses described herein may have certain capabilities, including storing products in a computerized storage unit, retrieving products from storage, restoring products previously retrieved from storage, displaying products' stored data, renaming products in storage, renaming the data of products in storage, creating categories for data, organizing data within created categories, printing products' stored data, or providing physical and/or electronic access to the data stored in the stored products remotely through wired or wireless data transmission.

Referring to FIG. 1A, an exemplary embodiment of storage system 100 is shown. System 100 may include an enclosure 102, a display 104 that can contain an interface 124, an access opening 106, and plurality of controls 108-122. In other exemplary embodiments, display 104 may be located remotely from system 100. For example display 104 may be connected in a wired or wireless fashion to system 100 and may be any type of display, such as a stand-alone display or a display connected with a computer or system, and the like. System 100 may also include internal components not pictured in FIG. 1A, which are discussed below. Enclosure 102 and any other portions of system 100 can be formed in any manner desired and out of any materials, for example plastic, metal, or any combination of materials.

Still referring to FIG. 1A, controls 108-122 can be buttons, toggles, switches, or any other known control components. In one exemplary embodiment, control 108 can be used to turn power for systems 100 on and off, control 110 can be used to call up a menu, control 112 can be used to toggle a selection, control 114 can be used to enter a selection, control 116 can control a print command, control 118 can be used to control an skip command, control 120 can be used to control an eject command, and control 122 can be used to control a store command. In other exemplary embodiments, controls 108-122 can be configured to suit any other control scheme as desired and may be reconfigured by a user or any other desired entity.

Turning to FIG. 1B, display 104 can be a liquid crystal display (LCD), a light-emitting diode (LED) display, touch screen display, or any other type of display known in the art. Display 104 can contain interface 124, which can contain a header area 126, a command control area 128, a plurality of input control areas 130-134, a command management display 136, and a message communication area 138, as well as any other command interface objects. Header area 126 can be used to indicate which function system 100 is performing Command control area 128 can indicate which inputs are necessary for system 100 to perform a specific function. Input control area 132 can display a list of available inputs. Input control area 134 can display a list of available actions that can be taken. Control 112 can be used to toggle between selections in input control areas 132 and 134, and control 114 can be used to make a selection.

In some alternative exemplary embodiments, any other control 108-122 can be used to make selections, using any other type of control scheme, as desired. Input control area 130 can display selections made in input control areas 132 and 134. Command management display 136 can display information that has been stored in system 100 that is related to a selection that is being made or has been made. Message communication area 138 can display instructions related to a selection that is being made or has been made.

Still referring to FIG. 1B, system 100 may include access opening 106 in which a data storage device, product, or receptacle containing a product, may be inserted. Access opening 106 may also be used to eject a product from the system 100. Alternatively, a separate access opening (not shown) may be used to eject a product from the system 100. The insertion or ejection of data storage devices may be coordinated using controls 108-122 and interface 124 on display 106.

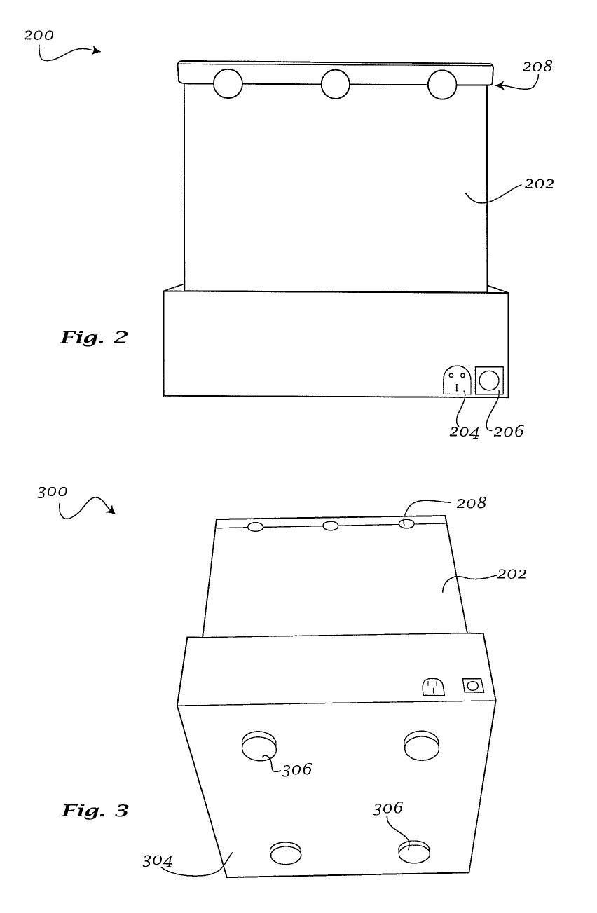

FIG. 2 can illustrate a portion of the rear of an exemplary embodiment of system 100. In the exemplary embodiment shown, a rear panel 202 may be made of metal, plastic, or any desired material or combination of materials, similar to materials that may be used for any other desired portion of system 100. The rear of the system 100 may include a receptacle or protrusion 204 for insertion of a power cable for system 100. The rear of the system 100 may also include a port 206 or multiple ports that may used to communicate with other devices. These ports could include Universal Serial Bus (USB) ports, Ethernet ports, Serial communication ports, Serial Advanced Technology Attachment ports, High Definition Media Output ports, Digital Video Input ports, Firewire ports, Parallel ports, TRS connector ports, and Small Computer System Interface ports, or any other type of connector or port. These and any other desired ports may allow for communication between system 100 and other desired systems, for example to display information or data, print information or data, or manipulate information or data in any other desired manner. The rear panel 202 may include a hinge 208 which may allow the top portion of enclosure 102 to be opened or closed to provide access to the inside of the system, for example allowing a user to manually retrieve any desired contents of enclosure 102.

FIG. 3 may illustrate a bottom and rear view of an exemplary embodiment of system 100. The rear panel 202 may include a hinge 208, as described above. The bottom portion 304 of system 100 may include structures 306 which may provide support or surface friction. Structures 306 may be pads, rubber shoes or any other desired support of friction-providing structures.

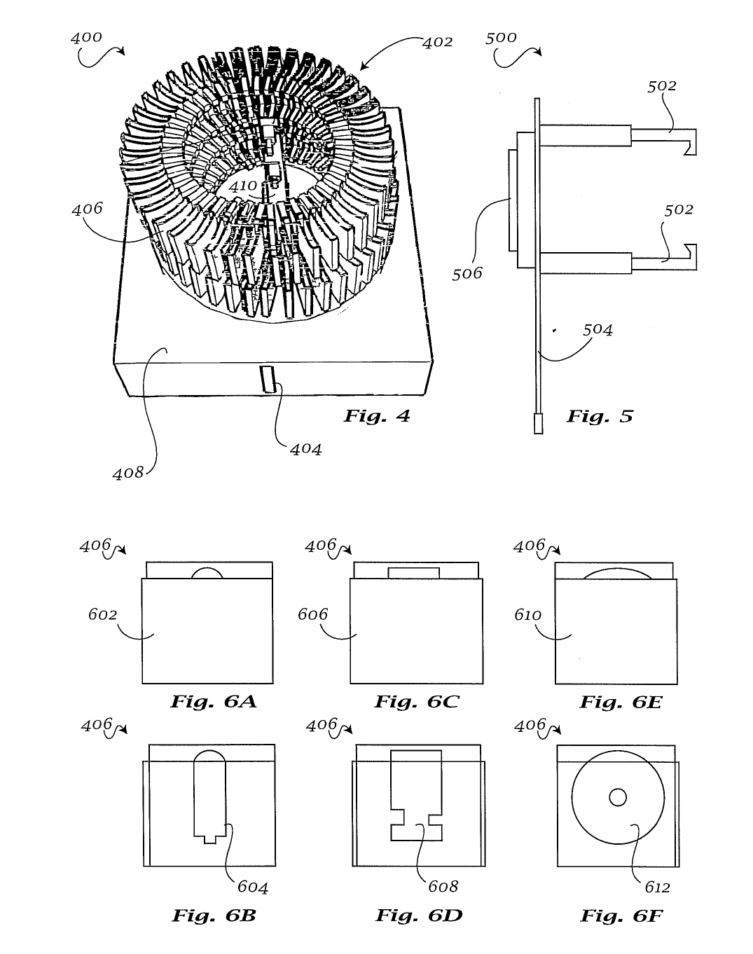

Referring to FIG. 4, an automated data storage device receiving, storing and sorting mechanism 400 of system 100 may appear as shown in this exemplary embodiment. The mechanism 400 may be housed in enclosure 102 and may include a base platform 408, on which a storage receptacle holder 402 may be able to rotate up to 360 degrees either clockwise or counterclockwise. In an exemplary embodiment, the storage receptacle holder 402 may hold a variety of different storage receptacles of varying shapes and sizes. Typical types of products that may be stored in the storage receptacle holder 402, in an exemplary embodiment, include Flash drives, USB drives, memory cards, memory sticks, CDs, DVDs, and any other objects with similar configurations or usage as described herein.

Still referring to exemplary FIG. 4, a storage receptacle 406 held within the storage receptacle holder 402, in an exemplary embodiment, may be interlocked with other storage receptacles such that their rotational movements are synchronized. The storage receptacle 406 may be formed out of plastic, metal, or any other desired material, and may be sized and shaped to hold any type of, for example, data storage devices. Also depicted in FIG. 4 may be the slot or receiver 404 which may receive data storage devices or products. Mechanism 400 may be mounted inside system 100 in such a way that slot or receiver 404 corresponds with slot or receiver 106, and may in that manner provide access to mechanism 400 from the outside of system 100. Control arm 410 may be located inside storage receptacle holder 402.

Control arm 410 may appear as shown in FIG. 5. Control arm 410 can interact with the storage receptacle holder 402. Control arm 410 can move in various directions, including up and down, and clockwise and counterclockwise, in order to engage storage receptacle holder 402. Control arm 410 can make use of gripping extensions 502 to grip storage receptacles such as storage receptacle 406. Elevation mechanism 506 allows gripping extensions 502 to be moved into different positions on support beam 504. In this way, control arm 410 can receive storage receptacles such as storage receptacle 406 through slot 404 and reposition them to be deposited in storage receptacle holder 402. Control arm 410 can also move in such a way that it can retrieve storage receptacles such as storage receptacle 406 from storage receptacle holder 404 and can then place them through slot 404 for extraction from mechanism 400.

Storage receptacle 406 may appear as shown in FIGS. 6A-6F. Storage receptacle 406 may be configured to hold a variety of different objects, for example flash drives, USB drives, Compact Disks, Digital Video Disks, memory cards, memory sticks, and any other similar objects, as described herein. In one exemplary embodiment, storage receptacle 406 can have a body 602, as shown in FIG. 6A, with a defined recess 604, as shown in FIG. 6B. Recess 604 can be sized and shaped to hold a USB drive or any other data storage device having a similar size or shape.

In another exemplary embodiment, and as shown in exemplary FIG. 6C, storage receptacle 406 can have a body 606, with a defined recess 608, as shown in FIG. 6D, that may be sized and shaped to hold a flash memory card. In still another exemplary embodiment, storage receptacle 406 can have a body 610, as shown in FIG. 6E, with a defined recess 612, as shown in FIG. 6F, that may be sized and shaped to hold a Compact Disk or Digital Video Disc. In further exemplary embodiments, any size or shape data storage device may be coupled with a receptacle having a similarly sized aperture so as to allow the data storage device to be stored in system 100. Also, in some alternative exemplary embodiments, a storage receptacle 406 may have an appearance of any of the receptacles shown in exemplary FIGS. 6A-6F, but may further be adapted to universally accept any size, shape or type of data storage device. For example, receptacle 406 in FIG. 6F may be shown to accept a CD or DVD in recess 612, but it may also accept and act as a receptacle for any other form of data storage device, such as a USB drive, flash memory card or any other desired data storage device. Such a receptacle 406 could then universally accept data storage devices and be inserted into system 100.

As an example, system 100 may be operated in a manner as described below. System 100 may be powered on using control 108. Then, control 110 can be used to call up a menu on display 104. Control 112 may then be used to highlight a function, for example a “Store Object” function displayed on the menu on display 104. Control 114 may then be used to accept the “Store Object” function and, additionally, call a sub-menu with “Store Object” on header area 126. Control 112 may then be used to enter any desired text in input control area 130, for example by making selections from input control area 132. Additionally, control 112 can be used to initiate any desired system commands against input control area 130, for example by making selections from input control area 134.

Following the entry of any desired text into input control area 130, control 114 can be used to accept the entered text and prepare system 100 for product insertion into storage receptacle 406. Gripping extension 502 of control arm 410 can then engage storage receptacle 406, for example moving it into mechanism 400 through slot 404 and access opening 106. A desired product may then be placed into a defined recess of a storage receptacle 406. Control 122 can then be used to prepare the control arm 410 for insertion of a storage receptacle 406 into the storage receptacle holder 402 for storage. Additionally, any desired text entries and system command instructions on display 104 may be submitted or finalized using control 114.

In different exemplary embodiments system 100 can be used in any way, for example ejecting an object, re-storing a previously stored object, displaying information related to a stored object, renaming a stored object, printing information related to a stored object, or deleting a stored object. These and any other desired functions may allow for ease and convenience in the storage, sorting, naming, and retrieving of any data storage devices

The foregoing description and accompanying drawings illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

What is claimed is:

1. A storage apparatus, comprising:
a case, the case having at least one aperture defined there on;
an automated data storage device receiving, storing and sorting mechanism located aft of the at least one aperture;
storage capacity for a plurality of data storage devices; and
a user interface.

2. The storage apparatus of claim 1, wherein the at least one aperture is sized to receive at least one of the plurality of data storage devices.

3. The storage apparatus of claim 1, wherein the at least one aperture is sized to receive a receptacle holding at least one of the plurality of data storage devices.

4. The storage apparatus of claim 1, wherein the receptacle is a housing that holds and secures the data storage device in a recess shaped similar to a data storage device.

5. The storage apparatus of claim 1, the plurality of data storage devices comprising at least one of digital video discs, compact discs, flash drives, universal serial bus drives, memory sticks and memory cards.

6. The storage apparatus of claim 1, further comprising a hinged door at a top portion of the case that facilitates the manual retrieval of the plurality of data storage devices of from the internal storage device.

7. The storage apparatus of claim 1, automated data storage device receiving, storing and sorting comprises:
a storage receptacle holder that stores the plurality of data storage devices for organization and retrieval; and
a control arm that cooperatively engages the storage receptacle holder to place and retrieve storage receptacles and passes storage receptacles through the aperture in the enclosure.

8. The storage apparatus of claim 1, wherein the user interface comprises a display.

9. The storage apparatus of claim 8, wherein the display is a touch screen display.

10. The storage apparatus of claim 1, wherein the user interface comprises a plurality of buttons.

11. The storage apparatus of claim 10, wherein the plurality of buttons manipulate data on a display.

12. The storage apparatus of claim 1, wherein the user interface facilitates the storage of the plurality of data storage devices, the sorting of the plurality of data storage devices, the naming of the plurality of data storage devices and the retrieval of the plurality of data storage devices.

13. The storage apparatus of claim 1, wherein the user interface facilitates actuation of the automated data storage device receiving, storing and sorting mechanism.

14. A method for storing and organizing data storage devices, comprising:
placing a data storage device into storage receptacle;
moving the storage receptacle to an inside portion of an enclosure;
sorting the storage receptacle according the data storage device in the storage receptacle;
performing management tasks;
retrieving the storage receptacle from the enclosure; and
ejecting the data storage device.

15. The method of claim 14, further comprising preparing a device housing the enclosure for an insertion of the data storage device.

16. The method of claim 14, wherein management tasks include at least one of preparing a device housing the enclosure for receiving or taking in data storage device, preparing the device housing the enclosure for ejecting a data storage device, selecting a particular data storage device stored, and performing an operation on a desired data storage device.

17. The method of claim 16, wherein performing an operation on a selected product includes at least one of renaming, deleting, displaying, and printing.

18. The method of claim 14, further comprising actuating a mechanical arm for the moving, sorting and retrieving.

19. A system for storing digital media, comprising:
means for programming data;
means for mechanically accepting various formats of digital media;
means for mechanically storing the various formats of digital media;
means for mechanically sorting the various formats of digital media;
means for reading the various formats of digital media;
means for naming the various formats of digital media; and
means for retrieving the various formats of digital media.

20. The system of claim 19, further comprising means for manipulating data found on the various formats of digital media.
